(19) United States
(12) Patent Application Publication
(10) Pub. No.: US 2023/0140705 A1
(43) Pub. Date: May 4, 2023

(54) COOLING OF AN ELECTRONIC DEVICE

(71) Applicant: STMICROELECTRONICS (GRENOBLE 2) SAS, Grenoble (FR)

(72) Inventors: Younes BOUTALEB, Grenoble (FR); Romain COFFY, Voiron (FR)

(73) Assignee: STMICROELECTRONICS (GRENOBLE 2) SAS, Grenoble (FR)

(21) Appl. No.: 17/970,327

(22) Filed: Oct. 20, 2022

(30) Foreign Application Priority Data
Oct. 29, 2021 (FR) 2111527

(51) Int. Cl. H01L 23/367; H01L 21/52; H01L 23/498

(52) U.S. Cl. CPC H01L 23/3675; H01L 21/52; H01L 23/49822; H01L 24/13

(57) ABSTRACT

The present description concerns an electronic device comprising an electronic chip and a package for protecting said chip, said package comprising: a substrate comprising an alternation of electrically-insulating layers and of thermally-conductive layers where at least one electrically-insulating layer comprises at least a thermally-conductive portion; and a cover made of a thermally-conductive material comprising at least one lateral portion arranged in at least one cavity formed from a first surface of said substrate.

### BACKGROUND

### Technical Field

The present disclosure generally concerns electronic systems and devices, and their protection and cooling means. The present disclosure in some embodiments applies to means for cooling an electronic device protected by a package.

### Description of the Related Art

Many techniques of cooling of electronic systems and devices protected by a package are known. For example, packages can be adapted to dissipating the heat generated by the components and circuits of the electronic device or system.

### BRIEF SUMMARY

An embodiment provides an electronic device comprising an electronic chip and a package for protecting said chip, said package comprising:
a substrate comprising an alternation of electrically-insulating layers and of thermally-conductive layers where at least one electrically-insulating layer comprises at least one thermally-conductive portion; and
a cover made of a thermally-conductive material comprising at least one lateral portion arranged in at least one cavity formed from a first surface of said substrate.

According to an embodiment, the device further comprises a layer made of a thermally-conductive material in contact with a second surface of said chip and with said cover.

According to an embodiment, a third surface of said chip is bonded to said first surface of said substrate.

According to an embodiment, said at least one cavity extends from said first surface of said substrate, and extends all the way to said at least one thermally-conductive portion.

According to an embodiment, said lateral portion of said cover is in contact with one of said thermally-conductive layers in contact with said thermally-conductive portion.

According to an embodiment, said lateral portion of said cover is in contact with said thermally-conductive portion.

According to an embodiment, said lateral portion of said cover is coupled to said thermally-conductive portion by a thermally-conductive via.

According to an embodiment, said cover is a metal cover.

According to an embodiment, said thermally-conductive layers are also electrically-conductive.

According to an embodiment, said cover further comprises a transverse portion.

According to an embodiment, said at least one lateral portion is bonded to said transverse portion.

According to an embodiment, said cover is made of a single block.

An embodiment provides a method of manufacturing an electronic device comprising the steps of:
(a) providing a substrate comprising an alternation of electrically-insulating layers and of thermally-conductive layers where at least one electrically-insulating layer comprises at least one thermally-conductive portion, said substrate further comprising at least one cavity formed from a first surface of said substrate;
(b) mounting an electronic chip on said first surface of said substrate;
(c) forming a layer made of a thermally-conductive material in contact with at least one second surface of said electronic chip; and
(d) arranging at least one lateral portion of a cover in said cavity formed of said substrate.

According to an embodiment, during step (b), a third surface of said chip is bonded to said first surface of said substrate.

According to an embodiment, the method further comprises a step (d) of bonding of a transverse portion of said cover to said at least one lateral portion of said cover.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows a cross-section view of an embodiment of an electronic device;

FIG. 2 shows a cross-section view of another embodiment of an electronic device;

FIG. 3 shows three cross-section views illustrating steps of an implementation mode of a method of manufacturing the electronic device of FIG. 1;

FIG. 4 shows three cross-section views illustrating other steps of an implementation mode of a method of manufacturing the electronic device of FIG. 1; and

FIG. 5 shows a cross-section view of another embodiment of an electronic device.

### DESCRIPTION OF THE EMBODIMENTS

Like features have been designated by like references in the various figures. For example, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and in some embodiments within 5%.

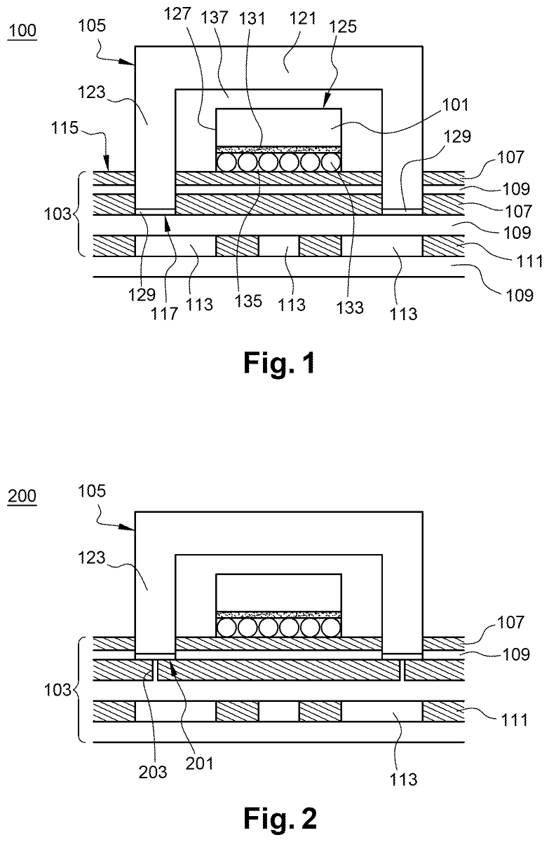

FIG. 1 is a side cross-section view of an embodiment of an electronic device 100.

Electronic device 100 comprises an electronic chip 101 protected by a protection package formed of a substrate 103 and of a cover 105 made of a thermally-conductive material.

Substrate 103 is a laminated substrate formed of a stack of layers alternating electrically-insulating layers 107 (hatched in FIG. 1) and thermally- and, for example, electrically-conductive layers 109. In FIG. 1, substrate 103 comprises three insulating layers 107 and three conductive layers 109. According to an example, layers 107 and 109 have equal thicknesses, or variable thicknesses. According to an example, each layer 107 has a thickness in the range from 10 μm to 100 μm and each layer 109 has a thickness in the range from 10 μm to 30 μm. According to an example, layers 107 are made of an electrically-insulating material such as a material formed of glass fibers embedded in an insulating resin, one or a plurality of ABF-type films (Ajinomoto Build-Up Film). A layer 107 may be made of an electrically-insulating material compatible with a surface deposition (to protect the metals located below). According to an example, layers 109 are made of a thermally-conductive material, and which may also be electrically-conductive such as, for example, copper.

According to an embodiment, substrate 103 comprises an insulating layer 111 comprising at least one, in some embodiments a plurality of, thermally- and for example electrically-conductive portions 113. Insulating layer 111 may be any layer 107 of substrate 103, but one of the thickest layers 107 is in some embodiments selected to form layer 111. In FIG. 1, layer 111 corresponds to the third layer 107, starting from the upper surface 115 of substrate 103. According to an example, portions 113 are made of the same material as conductive layers 109.

According to an embodiment, substrate 103 further comprises one or a plurality of cavities 117, or trenches 117, formed from the upper surface 115 of substrate 103. Cavity or cavities 117 extend through one or a plurality of insulating layers 107 and one or a plurality of conductive layers 109. In FIG. 1, cavities 117 extend from upper surface 115 and through two insulating layers 107 and one layer 109. According to an embodiment, the bottom of cavity or cavities 117 emerges onto a conductive portion 113 of layer 111, or onto a conductive layer 109 in contact with a conductive portion 113 of layer 111. According to an embodiment, the dimensions of cavity or cavities 117 are defined by the dimensions of cover 105.

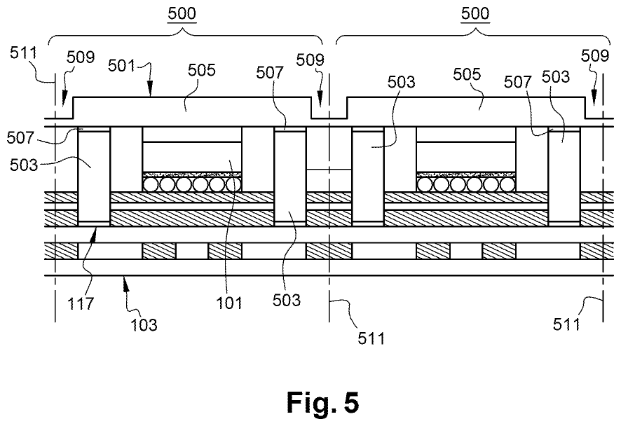

As previously mentioned, cover 105 is a cover made of a thermally-conductive material. According to an example, cover 105 is a metal cover. According to an example, the cover is made of copper or of an alloy comprising copper. Cover 105 comprises a transverse portion 121 extending substantially parallel to surface 115 of substrate 103, and lateral portions 123 substantially extending orthogonally to surface 115 of the substrate. According to an example, transverse portion 121 and lateral portions 123 each are plates with a substantially constant thickness, for example having a thickness in the range from 0.3 mm to 2 mm, for example in the order of 1 mm. According to an example, cover 105 is made of a single part comprising portions 121 and 123 but, according to a variant, described in further detail in relation with FIG. 5, portions 121 and 123 may be parts bonded to one another to form cover 105, for example, bonded by gluing.

Cover 105 is arranged on chip 101 to protect upper surface 125 and the lateral surfaces 127 of chip 101. Further, according to an embodiment, at least one lateral portion 123 of cover 105 has an end placed in the cavity 117 or in one of the cavities 117 of substrate 103. Cover 105 is for example bonded to substrate 103 via a glue layer 129.

Chip 101 is mounted on substrate 103 and is covered with cover 105. In some embodiments, the lower surface 131 of chip 101, that is, the surface opposite to upper surface 125 and which corresponds to an active area of chip 101, is bonded to the surface 115 of substrate 103. The active area of an electronic chip is the portion of the electronic chip having most of the electronic components of the chip and the electric contacts which enable the chip to be used formed therein. Further, chip 101 is bonded to substrate 103 via:
electric connectors 133, for example, electric connection balls or metal pillars, coupling contacts flush with surface 131 of chip 105 (not shown in FIG. 1) and contacts flush with surface 115 of substrate 103; and
a filling material 135 filling the spaces between connectors 133, and being in contact with surface 131 of chip 101 and surface 115 of substrate 103.

Further, a layer 137 made of a thermally-conductive material thermally couples the upper surface 125 of chip 101 and the lateral portion 121 of cover 105. Layer 137 may extend over all or part of surface 125 of chip 101. According to an example, layer 137 is formed at the level of one or a plurality of hot spots of chip 101, that is, of areas of surface 125 generating the greatest amount of heat. Layer 137 is made of a thermally-conductive material selected from the group comprising: the material bearing reference SE4450 commercialized by Dow Corning, and the material bearing reference TC3040 commercialized by Dow Corning.

An advantage of device 100 is that it enables to efficiently remove the heat generated by the hot spots of the upper surface 125 of chip 101. Indeed, when heat is generated by chip 101, this heat is conducted by layer 137, and then by cover 105, and is diffused in substrate 103, and in some embodiments in the thermally-conductive layers 109 and portions 113. A more conventional device, where the cover is simply glued to the upper surface of substrate 101, will remove approximately 10% less heat.

FIG. 2 is a side cross-section view illustrating an embodiment of an electronic device 200.

Electronic device 200 has elements common with the electronic device 100 described in relation with FIG. 1. These common elements are not described again herein, and only the differences between devices 200 and 100 are highlighted.

Electronic device 200 differs from device 100 in that the cavity or cavities 117 of substrate 103 are replaced with one or a plurality of cavities 201 which do not extend all the way to a conductive portion 113 of layer 111, or all the way to a conductive layer 109 in contact with a conductive portion 113 of layer 111. The bottom of cavity or cavities 201 then is thermally connected to a conductive portion 113 of layer 111, or all the way to a conductive layer 109 in contact with a conductive portion 113 of layer 111 via one or a plurality of thermally-conductive vias 203.

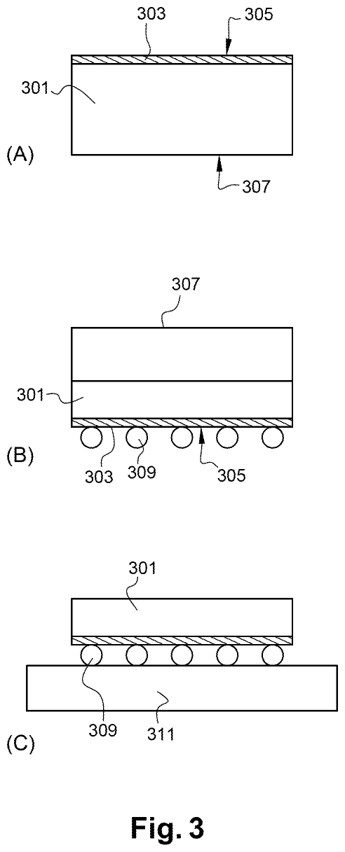

FIG. 3 shows three cross-section views (A), (B), and (C) illustrating steps of an implementation mode of a method of manufacturing a device of the type of the device 100 described in relation with FIG. 1.

Views (A), (B), and (C) illustrate an example of the preparation for the mounting of a chip 301 on a substrate.

The steps illustrated in FIG. 3 are carried out while the chips are still in a wafer. For simplification, only one chip 301 is shown in FIG. 3.

At the step of view (A), the manufacturing of the components of the chips 301 of the type of the chip 101 of FIG. 1 is complete. Each chip 301 comprises an active area 303 arranged on the side of a surface 305 opposite to a surface 307.

At the step of view (B), connectors 309 of the type of the connectors 133 of FIG. 1 are formed at the level of contacts (not shown) of the active area 303 of each chip 301. As previously mentioned, connectors 309 are for example electric connection balls, or solder balls, or metal pillars, for example made of a metal alloy comprising tin, silver, and copper. According to an example, connectors 309 are obtained by hemispherical growth. The wafer having chips 301 formed therein is then flipped so that its surface 307 is accessible. The wafer having a plurality of chips formed therein may then be thinned from the back side so that its thickness is at a desired thickness.

At the step of view (C), a tape 311 is applied on the side of surface 305 to protect active surface 305 and connectors 309 during the thinning step. Once the wafer has been thinned, chips 301 are individualized, for example, by a singulation step, film 311 being removed before sawing or laser cutting.

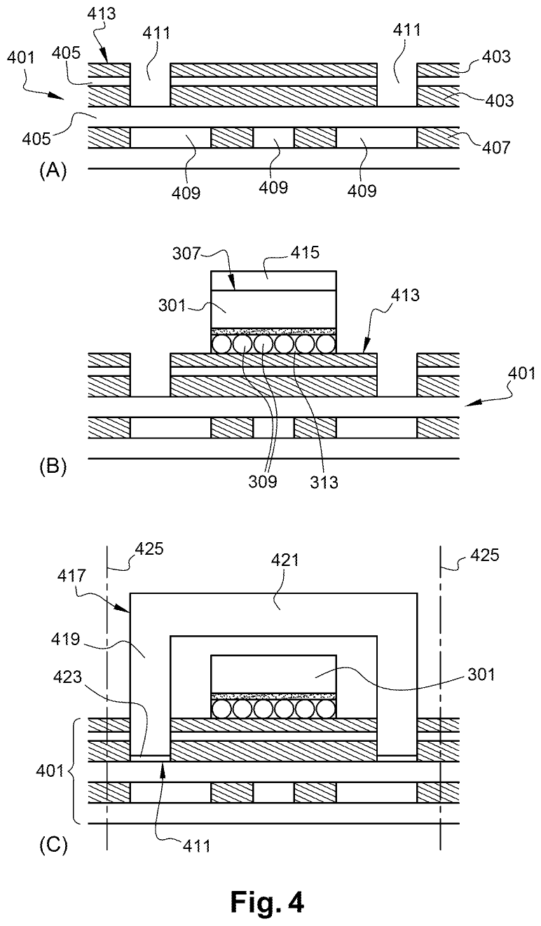

FIG. 4 shows three other cross-section views (A), (B), and (C) illustrating steps of an implementation mode of a method of manufacturing a device of the type of the device 100 described in relation with FIG. 1.

Views (A), (B), and (C) illustrate an embodiment of the mounting of the chip 301 of FIG. 3 on a substrate 401.

At the step of view (A), the manufacturing of substrate 401 of the type of the substrate 103 of FIG. 1 is complete. As previously described, substrate 401 is a laminated substrate formed of a stack of layers alternating electrically-insulating layers 403 (hatched in FIG. 1) and thermally- and, for example, electrically-conductive layers 405. Substrate 401 comprises an insulating layer 407, of the type of the layer 111 described in relation with FIG. 1, comprising at least one, in some embodiments a plurality of, thermally- and, for example, electrically-conductive portions 409. Substrate 401 further comprises one or a plurality of cavities 411 of the type of the cavity or the cavities 117 described in relation with FIG. 1, formed from the upper surface 413 of substrate 401. Cavity or cavities 411 extend through one or a plurality of insulating layers 403 and one or a plurality of conductive layers 405. In FIG. 4, the bottom of cavity or cavities 411 emerges onto a conductive layer 405 in contact with a conductive portion 409 of layer 407.

At the step of view (B), chip 301 is bonded to surface 413 of substrate 401 via connectors 309 and a filling material 313.

Further, at the step of view (B), a layer 415 made of a thermally-conductive material is formed over all or part of surface 307 of chip 301. According to an example, layer 415 may be formed over the entire surface 307 of chip 307 or only on the hot spot areas of surface 307 of chip 301. Layer 415 is of the type of the layer 137 described in relation with FIG. 1.

At the step of view (C), a cover 417 formed of a single block is arranged above chip 301. Cover 417 is of the type of the cover 105 described in relation with FIG. 1. Thus, cover 417 comprises lateral portions 419 and a transverse portion 421. The ends of lateral portions 419 are bonded at the bottom of cavities 411, for example, by a glue layer 423. The dimensions of cover 417 and of layer 415 are further adapted so that layer 415 is in direct contact with the transverse portion 421 of cover 417.

FIGS. 3 and 4 shown an implementation mode of a method of manufacturing a device of the type of the device 100 described in relation with FIG. 1. This method may be implemented in parallel to simultaneously manufacture a plurality of electronic devices. According to an example, for this purpose, substrate 401 may be a portion of a substrate plate of large dimensions from which a plurality of devices are formed. According to an example, the chips and the covers may be arranged in an array on the substrate plate, and the formed electronic devices may then be individualized, for example, by sawing. Examples of sawing lines 425 are shown by dotted lines in view (C) of FIG. 4.

FIG. 5 is a side cross-section view illustrating an embodiment of two identical electronic devices 500 formed side by side.

Electronic devices 500 have elements common with the electronic device 100 described in relation with FIG. 1. These common elements are not described again in detail herein, and only the differences between devices 500 and 100 are highlighted.

Electronic devices 500 differ from device 100 in that cover 105 formed of a single block is replaced with a cover 501 formed of a plurality of portions assembled together. In some embodiments, in cover 501, lateral portions 503 are assembled, or bonded, to transverse portion 505, for example, by a glue layer 507.

As concerns the method of manufacturing such an embodiment, two options are possible. The manufacturing method is similar to that described in relation with FIGS. 3 and 4, only the step of view (C) of FIG. 4 is modified.

In a first option (case shown in FIG. 5), at the step of view (C) of FIG. 4, the lateral portions 503 of cover 501 are placed in the cavities 117 of substrate 103, and then a plate intended to form the transverse portion 505 of cover 501 is bonded to lateral portions 503. The plate comprises notches 509, that is, portions having a smaller thickness than the thickness of the transverse portion 505 of cover 501 to ease the individualization of electronic devices 500. According to an example, the metal at the level of notches 509 has a thickness in the range from 100 to 150 μm. The width of the notches is for example in the range from 200 to 400 μm. Examples of sawing lines 511 are shown by dotted lines in FIG. 5.

In a second option (case not shown in FIG. 5), at the step of view (C) of FIG. 4, the lateral portions 503 of cover 501 are placed in the cavities 117 of substrate 103, and then the transverse portion is individually deposited to form each device 500.

Various embodiments and variants have been described. Those skilled in the art will understand that certain features of these various embodiments and variants may be combined, and other variants will occur to those skilled in the art. For example, the embodiments of FIGS. 2 and 5 may be combined.

Finally, the practical implementation of the described embodiments and variations is within the abilities of those skilled in the art based on the functional indications given herein.

Electronic device (100; 200; 500) may be summarized as including an electronic chip (101) and a package for protecting said chip (101), said package including a substrate (103) including an alternation of electrically-insulating layers (107) and of thermally-conductive layers (109) where at least one electrically-insulating layer (111) includes at least one thermally-conductive portion (113); and a cover (105; 501) made of a thermally-conductive material including at least one lateral portion (123; 503) arranged in at least one cavity (117) formed from a first surface (115) of said substrate (103).

Device may further include a layer (137) made of a thermally-conductive material in contact with a second surface (125) of said chip (101) and with said cover (105; 501).

A third surface (131) of said chip (101) may be bonded to said first surface (115) of said substrate (103).

Said at last one cavity (117) may extend from said first surface (115) of said substrate and extend all the way to said at least one thermally-conductive portion (113).

Said lateral portion (123; 503) of said cover (105; 501) may be in contact with one of said thermally-conductive layers (109) in contact with said thermally-conductive portion.

Said lateral portion (123; 503) of said cover (105; 501) may be in contact with said thermally-conductive portion.

Said lateral portion (123) of said cover (105) may be coupled to said thermally-conductive portion (113) by a thermally-conductive via (203).

Said cover (105; 501) may be a metal cover.

Said thermally-conductive layers (109) may be also electrically conductive.

Said cover (105; 501) may further include a transverse portion (121; 505).

Said at least one lateral portion (503) may be bonded to said transverse portion (505).

Said cover (121) may be made of a single block.

Method of manufacturing an electronic device (100) may be summarized as including the steps of (a) providing a substrate (401) including an alternation of electrically-insulating layers (403) and of thermally-conductive layers (405) where at least one electrically-insulating layer (407) includes at least one thermally-conductive portion (409), said substrate (401) further including at least one cavity (411) formed from a first surface (413) of said substrate (401); (b) mounting an electronic chip (301) on said first surface (413) of said substrate (401); (c) forming a layer (415) made of a thermally-conductive material in contact with at least one second surface (307) of said electronic chip (301); and (d) arranging at least one lateral portion (419) of a cover (417) in said cavity (411) formed of said substrate (401).

During step (b), a third surface (305) of said chip (301) may be bonded to said first surface (413) of said substrate (401).

Method may further include a step (d) of bonding of a transverse portion (505) of said cover (501) to said at least one lateral portion (503) of said cover (501).

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a substrate having a laminate of electrically-insulating layers and thermally-conductive layers arranged in an alternating manner, wherein an electrically-insulating layer of the electrically-insulating layers includes a thermally-conductive portion;
a semiconductor chip over a first surface of the substrate; and
a cover of a thermally-conductive material partially over the semiconductor chip and extending into a cavity in the substrate from the first surface of the substrate.

2. The device according to claim 1, further comprising a layer of a thermally-conductive material in contact with a first surface of the semiconductor chip and with the cover.

3. The device according to claim 2, wherein a second surface of the semiconductor chip is bonded to the first surface of the substrate.

4. The device according to claim 1, wherein the cavity extends from the first surface of the substrate to the thermally-conductive portion of the electrically-insulating layer.

5. The device according to claim 4, wherein the cover is in contact with a thermally-conductive layer of the thermally-conductive layers that is in contact with the thermally-conductive portion.

6. The device according to claim 4, wherein the cover is in contact with the thermally-conductive portion.

7. The device according to claim 4, comprising a thermally-conductive via coupled between the cover and the thermally-conductive portion.

8. The device according to claim 1, wherein the cover is a metal cover.

9. The device according to claim 1, wherein the thermally-conductive layers are electrically conductive.

10. The device according to claim 1, wherein the cover comprises a lateral portion and a transverse portion, the transverse portion overlapping the semiconductor chip, and the lateral portion extending into the cavity.

11. The device according to claim 10, wherein the lateral portion is bonded to the transverse portion.

12. The device according to claim 10, wherein the cover is made of a single block.

13. A method of manufacturing an electronic device, comprising:
providing a substrate including a stack of electrically-insulating layers and thermally-conductive layers arranged in an alternating manner, wherein an electrically-insulating layer of the electrically-insulating layers includes a thermally-conductive portion;
forming a cavity in the substrate from a first surface of the substrate;
mounting an electronic chip on the first surface of the substrate;
forming a layer of a thermally-conductive material in contact with a second surface of the electronic chip; and
arranging at least one lateral portion of a cover in the cavity.

14. The method according to claim 13, wherein the mounting the electronic chip includes bonding a third surface of the electronic chip to the first surface of the substrate.

15. The method according to claim 13, further comprising bonding a transverse portion of the cover to the at least one lateral portion of the cover.

16. A device, comprising:
a substrate comprising a first electrically-insulating layer, a second electrically-insulating layer, and a first thermally-conductive layer between the first electrically-insulating layer and the second electrically-insulating layer, the second electrically-insulating layer including a thermally-conductive portion;
a semiconductor chip over the first electrically-insulating layer of the substrate; and
a cover of a thermally-conductive material partially over the semiconductor chip and extending into the substrate through the first electrically-insulating layer.

17. The device according to claim 16, further comprising a layer of a thermally-conductive material in contact with a first surface of the semiconductor chip and with the cover.

18. The device according to claim 16, wherein the cover is in contact with the first thermally-conductive layer, and the first thermally-conductive layer chip is in contact with the thermally-conductive portion of the second electrically-insulating layer.

19. The device of claim 16, wherein the thermally-conductive portion extends through a thickness of the second electrically-insulating layer.

20. The device according to claim 16, further comprising a second thermally-conductive layer between the first electrically-insulating layer and the first thermally-conductive layer and a third electrically-insulating layer between the second thermally-conductive layer and the first thermally-conductive layer,
wherein:
the first thermally-conductive layer chip is in contact with the thermally-conductive portion of the second electrically-insulating layer,
the cover is in contact with the second thermally-conductive layer, and
the cover is coupled to the first thermally-conductive layer through a thermally-conductive via in the third electrically-insulating layer.
